(19) United States
(12) Patent Application Publication
(10) Pub. No.: US 2020/0145762 A1
(43) Pub. Date: May 7, 2020

(54) ACOUSTIC DEVICE AND METHOD OF FORMING THE SAME

(71) Applicant: Agency for Science, Technology and Research, Singapore (SG)

(72) Inventors: Navab Singh, Singapore (SG); Xiaolin Zhang, Singapore (SG); Wing Wai Chung, Singapore (SG)

(21) Appl. No.: 16/620,838

(22) PCT Filed: Jun. 19, 2018
(86) PCT No.: PCT/SG2018/050299

§ 371 Date: Dec. 9, 2019

(30) Foreign Application Priority Data
Jun. 28, 2017 (SG) 10201705332V

(51) Int. Cl. H04R 19/02; H04R 31/00; H04R 19/04; H04R 19/00; B81B 3/00; B81C 1/00

(52) U.S. Cl. CPC H04R 19/02; H04R 31/003; H04R 19/04; H04R 19/005; B81B 3/0021; B81C 2201/0105; H04R 2201/003; B81B 2201/0257; B81B 2203/0127; B81C 2201/013; B81C 1/00158

(57) ABSTRACT

Various embodiments may provide an acoustic device. The acoustic device may include a substrate, an electrically conductive first membrane, a first spacer holding the first membrane to form a first acoustic chamber between the substrate and the first membrane. The acoustic device may additionally include an electrically conductive second membrane, a second spacer holding the second membrane to form a second acoustic chamber between the first membrane and the second membrane, and a plurality of electrical pads in electrical connection with the first membrane and the second membrane.

### CROSS-REFERENCE TO RELATED APPLICATION

This application claims the benefit of priority of Singapore application No. 10201705332V filed on Jun. 28, 2017, the contents of it being hereby incorporated by reference in its entirety for all purposes.

### TECHNICAL FIELD

Various aspects of this disclosure may relate to an acoustic device. Various aspects of this disclosure may relate to a method of forming an acoustic device.

### BACKGROUND

Acoustics devices, such as microphones and speakers, are in high demand in consumer electronics. A microphone is a capacitive arrangement of a flexible membrane and a perforated black plate with both acting as electrodes. They are electrically isolated so that the output impedance is extremely high. The microphone may be implemented as a microelectromechanical system (MEMS). When there is a change in air pressure caused by sound, the flexible membrane moves with respect to fixed back plate, thus generating a change in capacitance, which can be detected. This change in capacitance is converted to an electrical signal by the readout control integrated circuit (IC) connected to the MEMS element. The operating voltage of the microphone may be quite low, at around a few volts. MEMS-based microphones are largely fabricated using silicon (Si) or poly-silicon (poly-Si) in the membrane or the back-plate, and silicon dioxide (SiO₂) in sacrificial layers. In such cases, the silicon dioxide is removed with ultrahigh selectivity to silicon using vapor hydrofluoric (VHF) acid.

A speaker, on the other hand, converts an electrical signal to sound using a vibrating flexible membrane. Vibrations in the membrane are created by a signal voltage applied on the membrane with respect to a fixed electrode. In a sense, the speaker may be structurally similar to microphone, although the speaker has an opposite function to that of the microphone. However, due to a requirement of a large change in sound pressure level, which is proportional to the acceleration of the moving membrane, the applied voltage used in speakers may be rather high—as high as 100V or more could be common. It means isolation features in speakers may need to have very high breakdown voltage and low leakage.

Another issue in the design of speakers relates to the generation of sounds at low frequencies, due to the fact that the acoustic Sound Pressure Level (SPL) generated is proportional to the membrane acceleration. As the acceleration declines linearly with frequency, the SPL generated falls sharply as frequency decreases. As such, all micro-speakers start their meaningful signal generation at ˜500 Hz to about ˜700 Hz. Lower frequencies typically require a sub-woofer speaker of much bigger dimensions, which are not achievable using MEMS technology with conventional speaker designs.

### SUMMARY

Various embodiments may provide an acoustic device. The acoustic device may include a substrate. The acoustic device may further include an electrically conductive first membrane. The acoustic device may also include a first spacer holding the first membrane to form a first acoustic chamber between the substrate and the first membrane. The acoustic device may additionally include an electrically conductive second membrane. The acoustic device may also include a second spacer holding the second membrane to form a second acoustic chamber between the first membrane and the second membrane. The acoustic device may additionally include a plurality of electrical pads in electrical connection with the first membrane and the second membrane. The first spacer may include a first semiconductor core, a first insulator layer between the first semiconductor core and the substrate, and a second insulator layer between the first semiconductor core and the first membrane. The second spacer may include a second semiconductor core, a third insulator layer between the second semiconductor core and the first membrane, and a fourth insulator layer between the second semiconductor core and the second membrane.

Various embodiments may provide a method of forming an acoustic device. The method may include forming an electrically conductive first membrane. The method may also include forming a first spacer holding the first membrane to form a first acoustic chamber between a substrate and the first membrane. The method may further include forming an electrically conductive second membrane. The method may additionally include forming a second spacer holding the second membrane to form a second acoustic chamber between the first membrane and the second membrane. The method may also include forming a plurality of electrical pads in electrical connection with the first membrane and the second membrane. The first spacer may also include a first semiconductor core, a first insulator layer between the first semiconductor core and the substrate, and a second insulator layer between the first semiconductor core and the first membrane. The second spacer may include a second semiconductor core, a third insulator layer between the second semiconductor core and the first membrane, and a fourth insulator layer between the second semiconductor core and the second membrane.

### BRIEF DESCRIPTION OF THE DRAWINGS

The invention will be better understood with reference to the detailed description when considered in conjunction with the non-limiting examples and the accompanying drawings, in which:

FIG. 1 shows an acoustic device or platform according to various embodiments.

FIG. 2 shows a general illustration of an acoustic device or platform according to various embodiments.

FIG. 3 is a schematic showing a method of forming an acoustic device or platform according to various embodiments.

FIG. 4A shows a substrate such as a silicon wafer being provided according to various embodiments.

FIG. 4B shows forming a first spacer according to various embodiments.

FIG. 4C shows forming a first membrane according to various embodiments.

FIG. 4D shows defining holes in the first membrane for sacrificial connectivity according to various embodiments.

FIG. 4E shows forming a second spacer according to various embodiments.

FIG. 4F shows forming a plug according to various embodiments.

FIG. 4G shows forming a second membrane according to various embodiments.

FIG. 4H shows defining holes in the second membrane for sacrificial connectivity according to various embodiments.

FIG. 4I shows forming a third spacer according to various embodiments.

FIG. 4J shows forming a plug according to various embodiments.

FIG. 4K shows forming a third membrane according to various embodiments.

FIG. 4L shows pre-metallization processing steps according to various embodiments.

FIG. 4M shows the forming of metal pads on the exposed portion of the third membrane according to various embodiments.

FIG. 4N shows the sacrificial release process according to various embodiments.

FIG. 5 shows a scanning electron microscopy (SEM) image of a tiled top view of a speaker device according to various embodiments.

FIG. 6 shows a cross-sectional image of a scanning electron microscopy (SEM) image of a speaker device according to various embodiments.

FIG. 7 shows a plot of leakage current (in amperes or A) as a function of bias voltage (in volts or V) showing electrical testing results of a fully fabricated device for leakage current and breakdown voltage between the membranes.

FIG. 8 shows an acoustic device or platform according to various embodiments.

FIG. 9 shows an acoustic device according to various embodiments.

FIG. 10 is a schematic showing a method of forming an acoustic device according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may also be used herein to mean that the deposited material may be formed “indirectly on” the implied side or surface with one or more additional layers being arranged between the implied side or surface and the deposited material. In other words, a first layer “over” a second layer may refer to the first layer directly on the second layer, or that the first layer and the second layer are separated by one or more intervening layers.

The device as described herein may be operable in various orientations, and thus it should be understood that the terms “top”, “topmost”, “bottom”, “bottommost” etc., when used in the following description are used for convenience and to aid understanding of relative positions or directions, and not intended to limit the orientation of the device.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

An alternative concept of generating a sound wave at low frequencies has previously been proposed. This concept generates an ultrasound wave modulated by sound wave of desired frequency, by simply applying such modulated voltage signal on the membrane, and then demodulates the sound wave by using a shutter arrangement functioning at ultrasound carrier frequency. This concept is interesting but its realization may be more difficult and may require a technology platform which could provide integrated shutter—stacked membranes separated by air chambers—with the flexible membrane etc. following high electrical breakdown voltage requirements.

Various embodiments may provide a technology platform to design and fabricate a stacked membrane based microphone device and/or a speaker device. The platform may include a substrate, stacked acoustic chambers on the substrate, perforated vibrating membranes vertically separating acoustic chambers, and spacers anchoring the membranes. The membranes may be isolated electrically from one another other and from the substrate. Large separation, high electrical breakdown, low stress effects, low electrical leakage, and high adhesion strength between the membranes may be obtained by selecting oxide wrapped un-doped poly-silicon as spacer material and creating dielectric thickness modulation and inter-digitization in the spacer designs. The top two membranes may act as integrated shutters. The platform may also allow to realize speaker devices based on modulation and demodulation of ultrasound waves.

Various embodiments may relate to a technology platform to design and fabricate a stacked membrane based acoustic MEMS device, such as a microphone and/or a speaker. The platform may provide a modular approach for stacking membranes on top of one another and may create air chambers between them. Separation between the membranes may be created by introducing spacers or standoffs crafted out of sacrificial materials, e.g. poly-silicon and silicon dioxide.

Spacers may be designed such that: (1) process is least complex, (2) there is no extra-long process steps, (3) stress effects are minimum and stable, (4) electrical breakdown is high, (5) electrical leakage through spacers is low, and (5) contact area between the membrane and spacer is large for a given space. To achieve all these phenomenon, poly-silicon may be used as a sacrificial material. However, to ensure that membranes, which are also made of poly-silicon (with doping for electrical conduction), remain protected in sacrificial release, they may be wrapped in silicon dioxide. Perforation in the membranes may be provided using lithography and etch process. In addition to the requirements from device functionality/design, perforation in the membranes may be utilized for sacrificial to sacrificial connections while making the platform multi-stack. The proposed vertically stacked membrane platform may allow design of high signal-to-noise ratio microphones and/or speakers with integrated shutters for modulations and demodulation of ultrasonic waves, which in turn may allow for generation of low frequencies sound without increasing membrane size and without using sub-woofers.

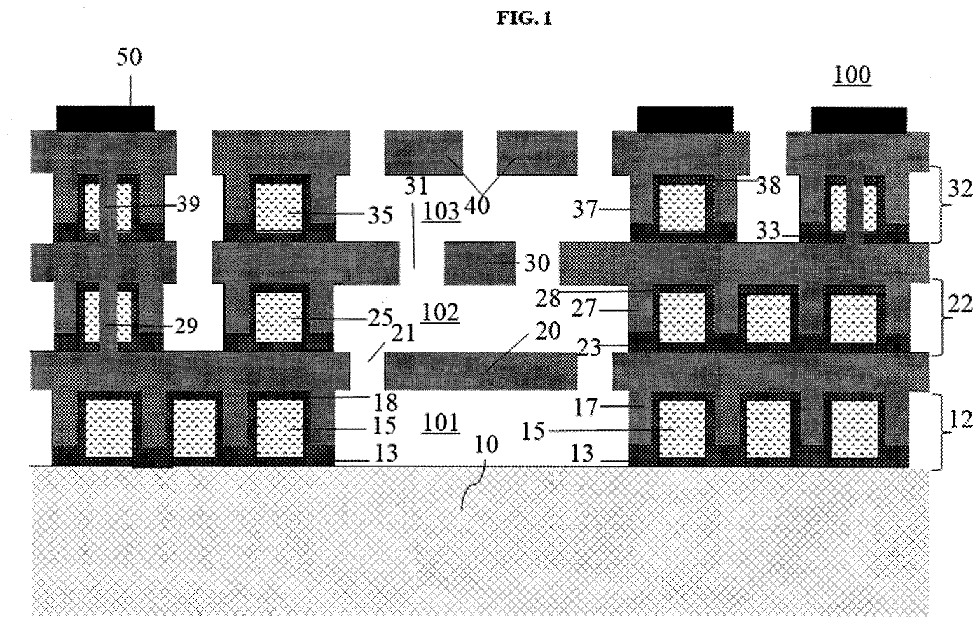

FIG. 1 shows an acoustic device or platform according to various embodiments. The acoustic device or platform 100 may include a substrate 10, for example a silicon substrate, covered with or wrapped a first insulator layer 13 including an insulator such as silicon dioxide layer. A first spacer 12 may be arranged on the front side of the substrate 10. The first spacer 12 may include the first insulator layer or silicon dioxide layer 13, sacrificial core semiconductor layer 15 including a suitable semiconductor such as poly-silicon, and a second insulator layer 18 including an insulator such as silicon dioxide.

A first membrane 20, including an electrically conductive material such as doped poly-silicon, may be arranged on top of first spacer 12, and may extend to or fill trenches 17, thus increasing contact area between the first membrane 20 and the first spacer 12. The poly-silicon may be doped with a dopant such as phosphorous with doping level between 10¹⁸ to 10²¹/cm³. The thickness of an insulator portion under trench 17 in the spacer 12 may define the electrical breakdown voltage. The thickness of this insulator portion may be approximately equal to the sum of the thickness of first insulator layer 13 and the second insulator layer 18.

The first semiconductor core 15, which may include un-doped poly-Si, together with first insulator layer 13 and the second insulator layer 18 may provide low electrical current leakage. The second insulator layer 18 may block the diffusion of the dopants from first membrane 20 to the first semiconductor core 15, and may thus retain the leakage current at low value. The thickness of the first spacer 12 may define the vertical dimension of the first air cavity/acoustic chamber 101. Second spacer 22, which is similar in design to first spacer 12, may be arranged on top of the first membrane 20 such that spacer 22 is in physical contact, but is in electrical isolation with the membrane 20. In order to apply electrical potential to membrane 20 for device functionality, hole 29 may be created in the spacer 22, and may be filled with an electrically conductive material such as poly silicon. In various embodiments, the electrically conductive material may be the poly silicon used to form second membrane 30. This way, first membrane 20 may be electrically connected to second membrane 30. A second membrane 30 may be arranged on top of second spacer 22. Next, a third spacer 32 may be arranged on top of second membrane 30. The design for spacers 12, 22, 32 may be identical. However, the thicknesses of the spacers 12, 22, 32 may be different, and may be adjusted to optimize the performance of specific devices for specific applications. Similarly, membrane thickness and/or perforation may be adjusted to achieve different resonance behavior.

A hole 39 may be drilled in the third spacer 32 to connect second membrane 30 to the third membrane 40, which may be arranged on top of third spacer 32. This way, when plug 29 is connected with plug 39, an electrical path from first membrane 20 to third membrane 40 may be formed. Accordingly, the metal pads 50 arranged on top of third membrane 40 may also be able to communicate electrically with the second membrane 30 as well as the first membrane 20. A first air chamber 101 may be formed between the substrate 10 and the first membrane 20, a second air chamber 102 may be formed between the first membrane 20 and the second membrane 30, and a third air chamber 103 may be formed between the second membrane 30 and the third membrane 40. By choosing an appropriate design and thickness, the second membrane 30 and the third membrane 40 may form a pair for membranes used as a shutter configured to provide demodulation of the modulated ultrasound wave generated by first membrane 20, thus producing a speaker function. In some cases, a hole may be drilled from the backside in the substrate 101 to access the first air chamber 101.

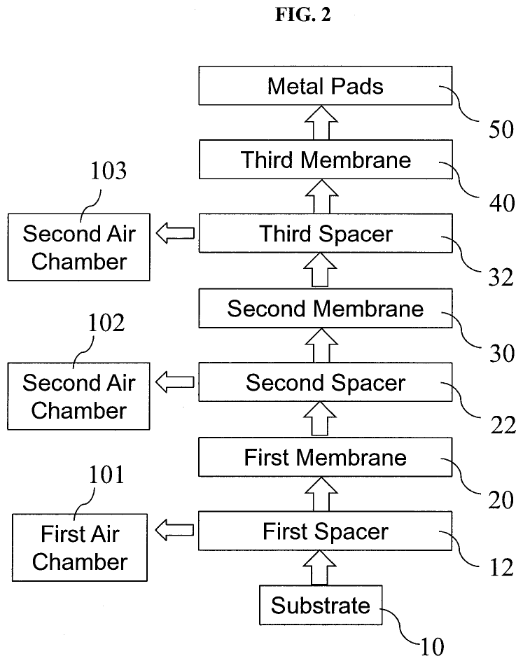

FIG. 2 shows a general illustration of an acoustic device or platform according to various embodiments. Various embodiments may relate to a modular design in which a sequence of a spacer and a membrane is repeated three times. However, various other embodiments may not be limited to three times. First spacer 12 and the first membrane 20 may be first arranged sequentially on top of the substrate 10. The arrangement may then be repeated by arranging second spacer 22, second membrane 30, third spacer 32 and then third membrane 40, followed metal pads 50, which are used for electrical probing. The removal of sacrificial material between the substrate 10 and the first membrane 20 may form the first air chamber 101, the removal of sacrificial material between the first membrane 20 and the second membrane 30 may form the second air chamber 102, while the removal of sacrificial material between the second membrane 30 and the third membrane 40 may form the third air chamber 103.

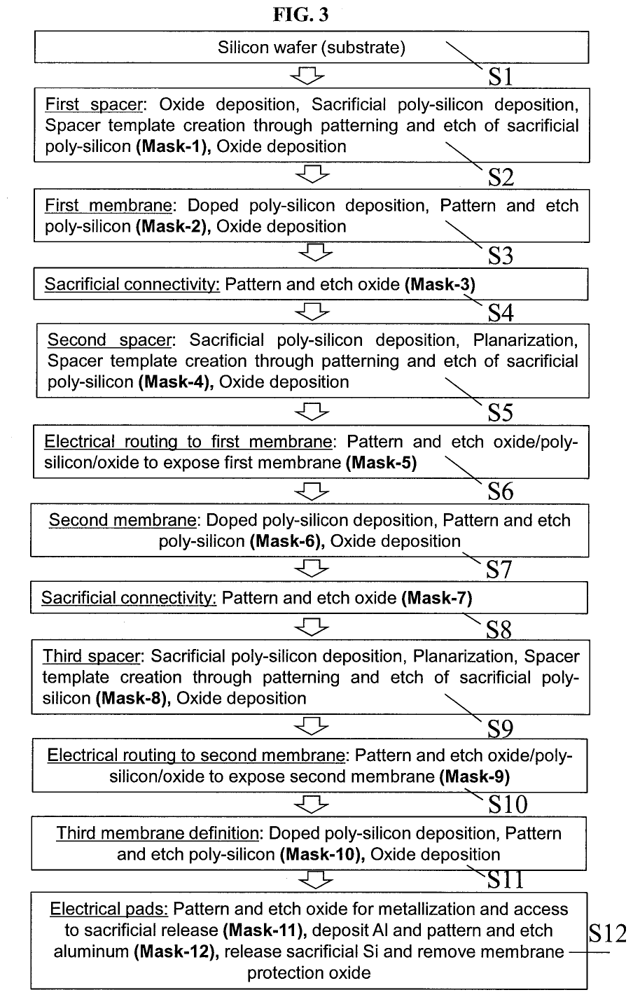

FIG. 3 is a schematic showing a method of forming an acoustic device or platform according to various embodiments. The method may include, in S1, providing a substrate such as a silicon wafer. The method may also include, in S2, forming the first spacer. The method may further include, in S3, forming the first membrane. The method may additionally include, in S4, defining holes in the first membrane for sacrificial connectivity. The method may also include, in S5, forming the second spacer. The method may also include, in S6, forming electrical routing to the first membrane. The method may additionally include, in S7, forming the second membrane. The method may further include, in S8, defining holes in the second membrane for sacrificial connectivity. The method may also include, in S9, forming the third spacer. The method may additionally include, in S10, forming electrical routing to the second membrane. The method may additionally include, in S11, defining the third membrane. The method may also include, in S12, forming electrical pads.

As shown in FIG. 3, the method may include twelve masking levels (M1-M12).

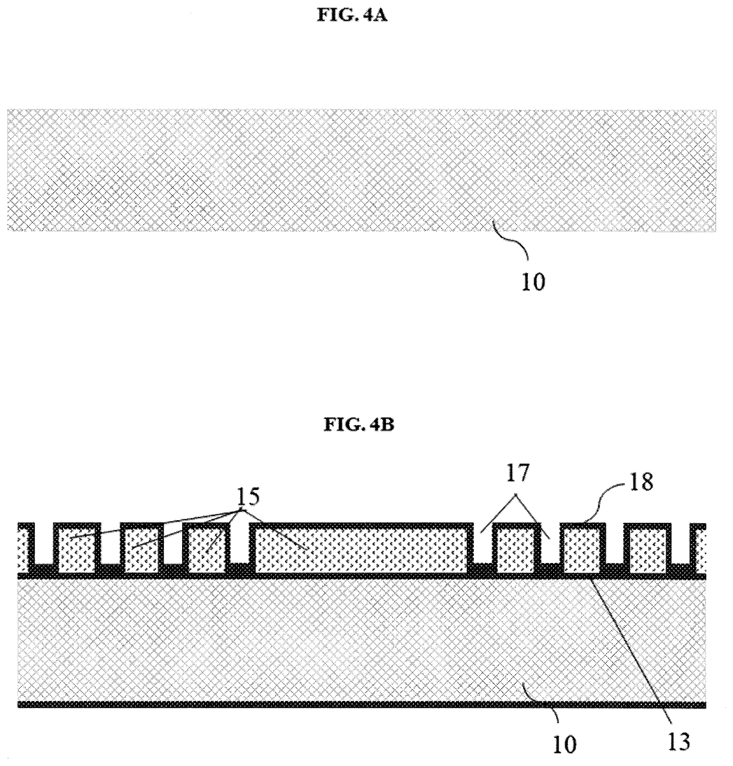

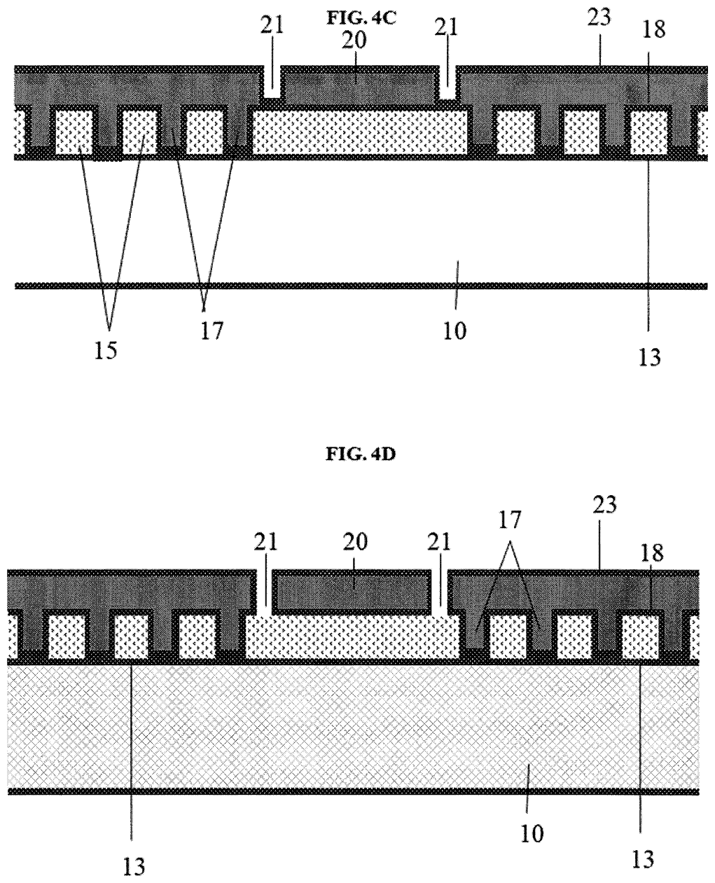

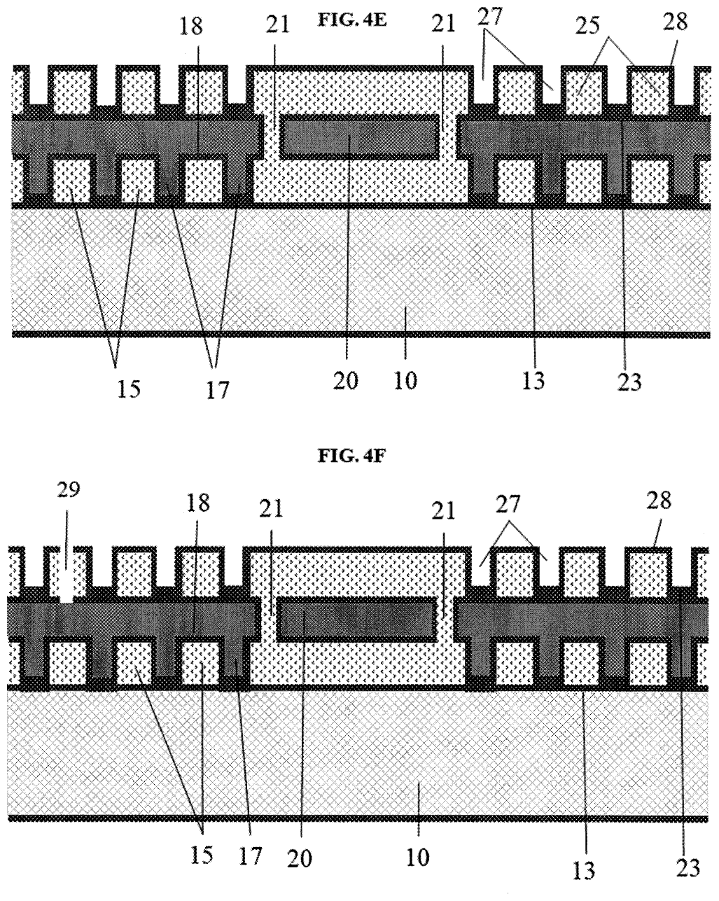

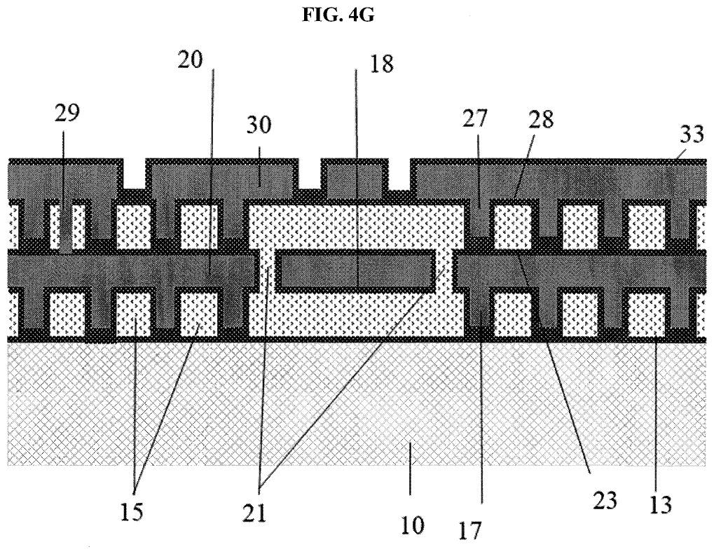

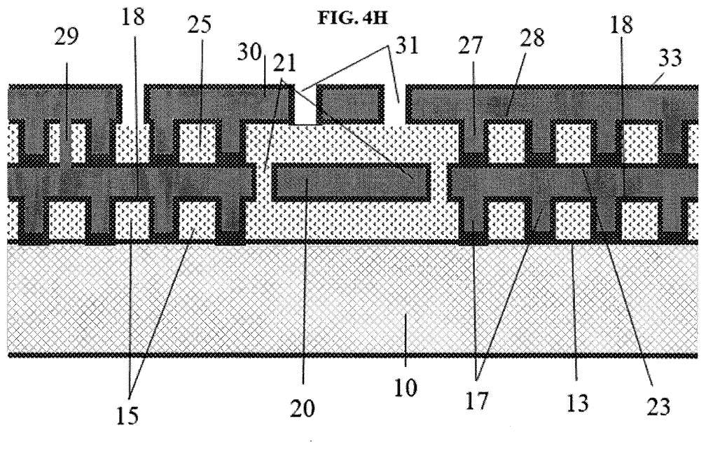

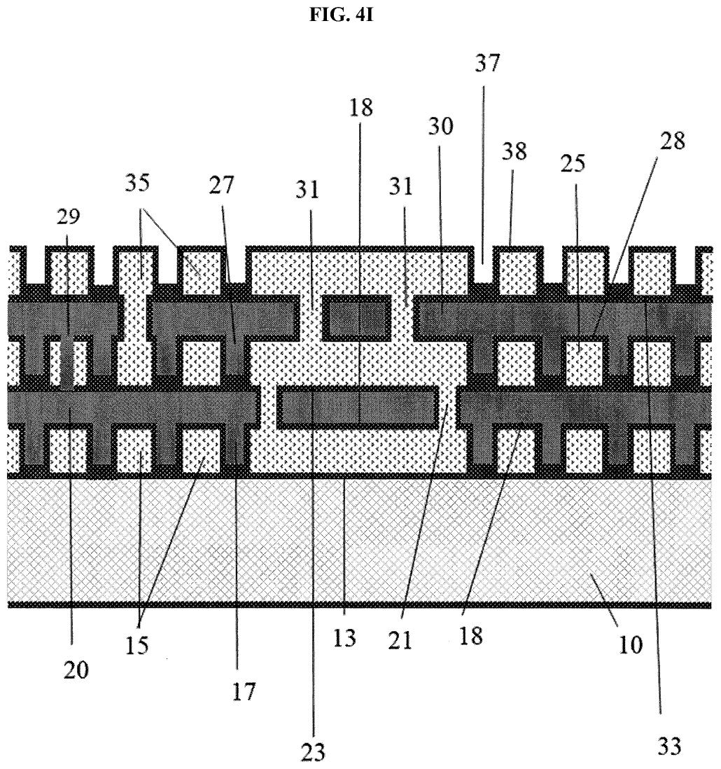

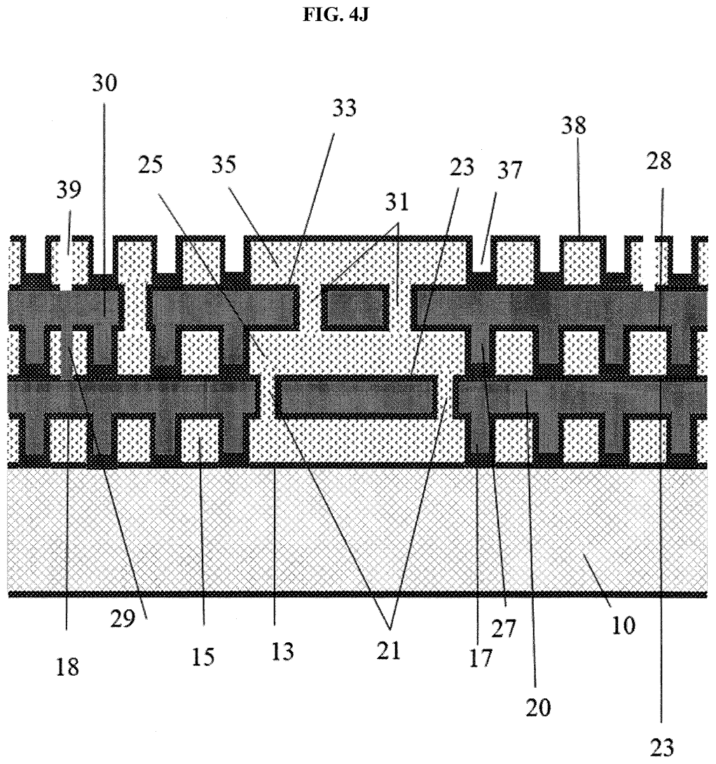

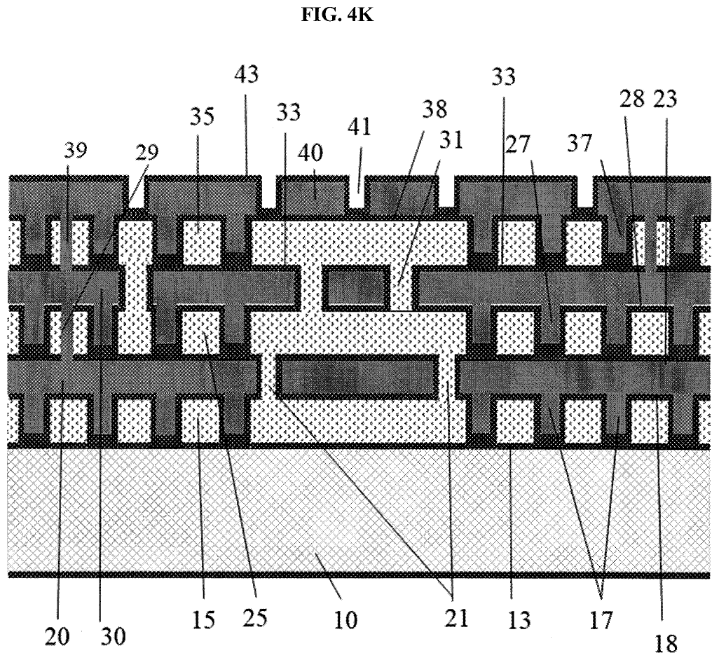

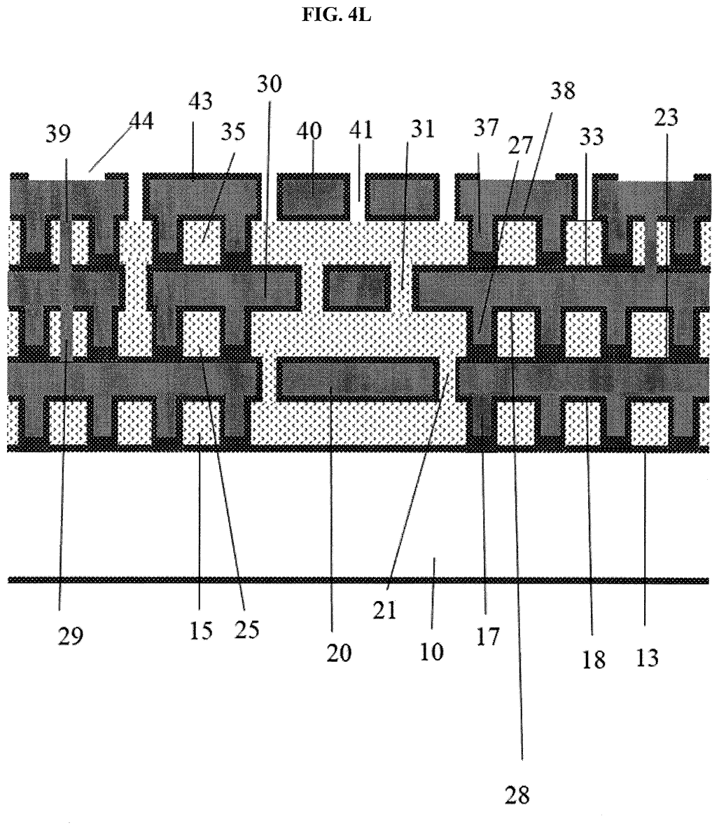

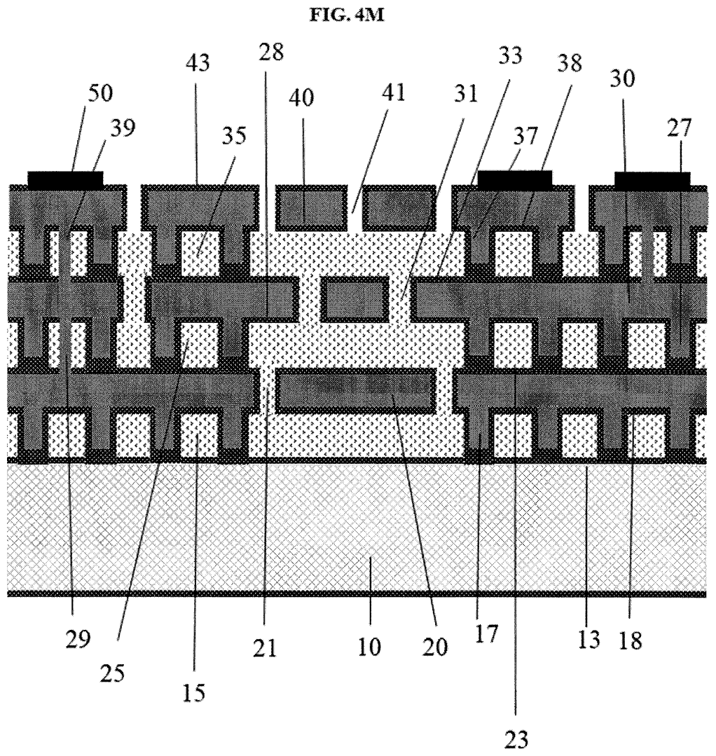

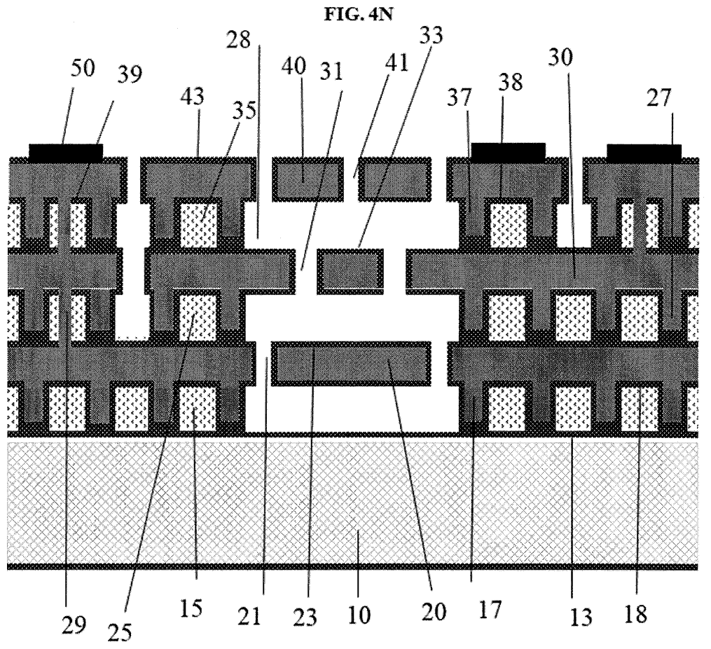

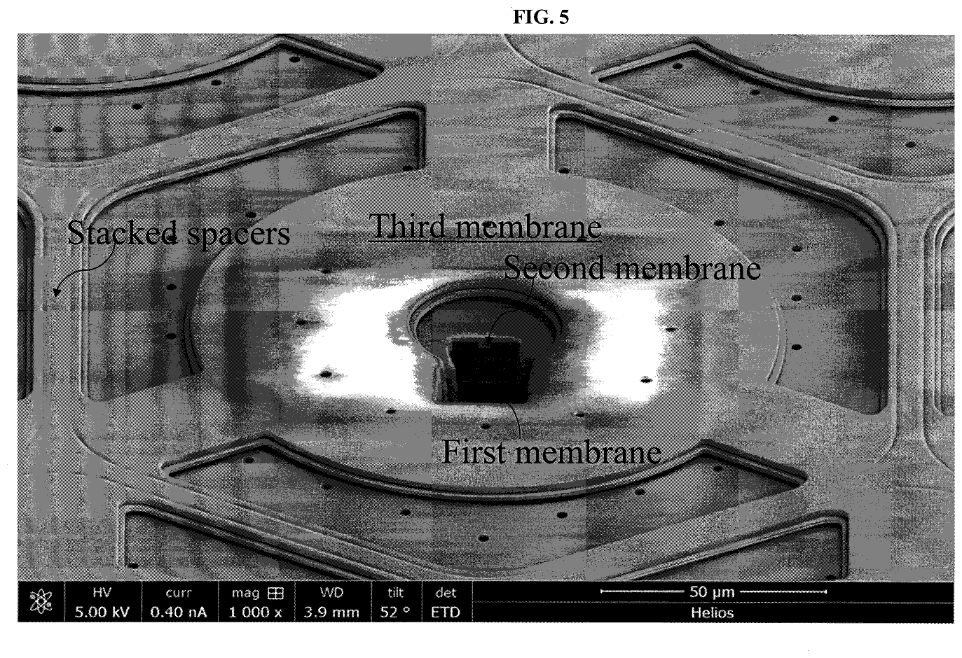

FIG. 4A shows a substrate 10 such as a silicon wafer being provided according to various embodiments. The substrate 10 may be a starting wafer to begin the fabrication process. FIG. 4B

FIG. 4B shows forming a first spacer according to various embodiments. An insulator material such as silicon oxide may be deposited onto the substrate 10 to form first insulator layer 13. A semiconductor material such as sacrificial poly-Si may be deposited on the first insulator layer 13, followed by patterning and etching to form a first semiconductor core 15 with trenches 17. An insulator material such as silicon oxide may then be deposited to form second insulator layer 18. A portion of the second insulator layer 18 inside trenches 17 may be in contact with a portion of the first insulator layer 13. Another portion of the second insulator layer 18 may be on or in contact with the first semiconductor core 15.

FIG. 4C shows forming a first membrane 20 according to various embodiments. An electrically conductive material such as doped poly-Si may be deposited, followed by planarization, patterning and etching to form the first membrane 20 with perforations 21. An insulator material such as silicon oxide may be deposited to form the third insulator layer 23. A portion of the third insulator layer 23 in perforations 21 may be in contact with a portion of the second insulator layer 18. Another portion of the third insulator layer 23 may be on the first membrane 20.

The removal of the sacrificial semiconductor core 15, including a material such as poly silicon 15, under the perforated membrane 20, constrained by spacer from all the lateral sides may provide or form the first air chamber. However, this removal may be carried out at the end of the process after completing full stacking.

FIG. 4D shows defining holes in the first membrane 20 for sacrificial connectivity according to various embodiments. The portion of the third insulator layer 23 and the portion of the second insulator layer 18 in contact with each other in perforations 21 may be removed. The removal of portions of the insulator layers 23, 18, including a material such as silicon oxide, may be required to make second sacrificial poly-silicon 25 in fluidic contact with the first sacrificial poly silicon 15 so that top down sacrificial release can take place at a later stage.

The above processes may be repeated to form the second spacer and the second membrane, as well as the third spacer and the third membrane.

FIG. 4E shows forming a second spacer according to various embodiments. A semiconductor material such as sacrificial poly-Si may be deposited on the third insulator layer 23, followed by planarization, patterning and etching to form a second semiconductor core 25 with trenches 27. An insulator material such as silicon oxide may then be deposited to form fourth insulator layer 28. A portion of the fourth insulator layer 28 inside trenches 27 may be in contact with a portion of the third insulator layer 23. Another portion of the fourth insulator layer 28 may be on or in contact with the second semiconductor core 25.

FIG. 4F shows forming a plug 29 according to various embodiments. The method may include creating an opening for electrical routing to the first membrane 20 by patterning and etching through the second spacer including the third insulator layer 23, the second semiconductor core 25, and the fourth insulator layer 28, i.e. until the first membrane 20 is exposed.

FIG. 4G shows forming a second membrane 30 according to various embodiments. An electrically conductive material such as doped poly-Si may be deposited, patterning and etching to form the second membrane 30 with perforations 31. The doped poly-Si may be deposited in the opening to form plug 29. The plug 29 may provide an electrical connection between the first membrane 20 and the second membrane 30. An insulator material such as silicon oxide may be deposited to form the fifth insulator layer 33. A portion of the fifth insulator layer 33 in perforations 31 may be in contact with a portion of the fourth insulator layer 28. Another portion of the fifth insulator layer 33 may be on the second membrane 30.

FIG. 4H shows defining holes in the second membrane 30 for sacrificial connectivity according to various embodiments. The portion of the fifth insulator layer 33 and the portion of the fourth insulator layer 28 in contact with each other in perforations 31 may be removed.

FIG. 4I shows forming a third spacer according to various embodiments. A semiconductor material such as sacrificial poly-Si may be deposited on the fifth insulator layer 33, followed by planarization, patterning and etching to form a third semiconductor core 35 with trenches 37. An insulator material such as silicon oxide may then be deposited to form sixth insulator layer 38. A portion of the sixth insulator layer 38 inside trenches 37 may be in contact with a portion of the fifth insulator layer 33. Another portion of the sixth insulator layer 38 may be on or in contact with the third semiconductor core 35.

FIG. 4J shows forming a plug 39 according to various embodiments. The method may include creating an opening for electrical routing to the second membrane 30 by patterning and etching through the second spacer including the fifth insulator layer 33, the third semiconductor core 35, and the sixth insulator layer 38, i.e. until the second membrane 30 is exposed.

FIG. 4K shows forming a third membrane 40 according to various embodiments. An electrically conductive material such as doped poly-Si may be deposited, followed by patterning and etching to form the third membrane 40 with perforations 41. The doped poly-Si may be deposited in the opening to form plug 39. The plug 39 may provide an electrical connection between the second membrane 30 and the third membrane 40. An insulator material such as silicon oxide may be deposited to form the seventh insulator layer 43. A portion of the seventh insulator layer 43 in perforations 41 may be in contact with a portion of the sixth insulator layer 38. Another portion of the seventh insulator layer 43 may be on the third membrane 40.

FIG. 4L shows pre-metallization processing steps according to various embodiments. The portion of the sixth insulator layer 38 and the portion of the seventh insulator layer 43 in contact with each other in perforations 41 may be removed for access to sacrificial release. In addition, a further portion 44 of the seventh insulator layer 43 may be patterned and etched for access to the underlying third membrane 40.

FIG. 4M shows the forming of metal pads 50 on the exposed portion of the third membrane 40 according to various embodiments. Forming the metal pads 50 may including depositing the metal, patterning and etching the metal to form pads 50. The metal pads 50 may include a metal such as aluminum. The pads 50 may be used for electrical probing.

FIG. 4N shows the sacrificial release process according to various embodiments. A suitable etchant may be introduced through perforations to remove semiconductor material such as sacrificial poly-Si that is not covered by the insulator material. The sacrificial release process may release portions of membranes 20, 30, 40.

Portions of the insulator layers 13, 18, 23, 28, 33, 38, 43 may be removed to form the device shown in FIG. 1. For instance, the insulator material such as oxide may be stripped.

In various embodiments, a hole may be formed, e.g. via drilling from a backside of the substrate 10 prior to removing sacrificial poly-Si (i.e. sacrificial poly-Si that is not covered by the insulator material shown in FIG. 4N) and protection oxide, i.e. portions of the insulator layers 13, 18, 23, 28, 33, 38, 43.

FIG. 5 shows a scanning electron microscopy (SEM) image of a tiled top view of a speaker device according to various embodiments. Various features are highlighted. Focused Ion Beam (FIB) cut may be applied to the center of the device to view the bottommost two membranes before stripping the wrapping oxide.

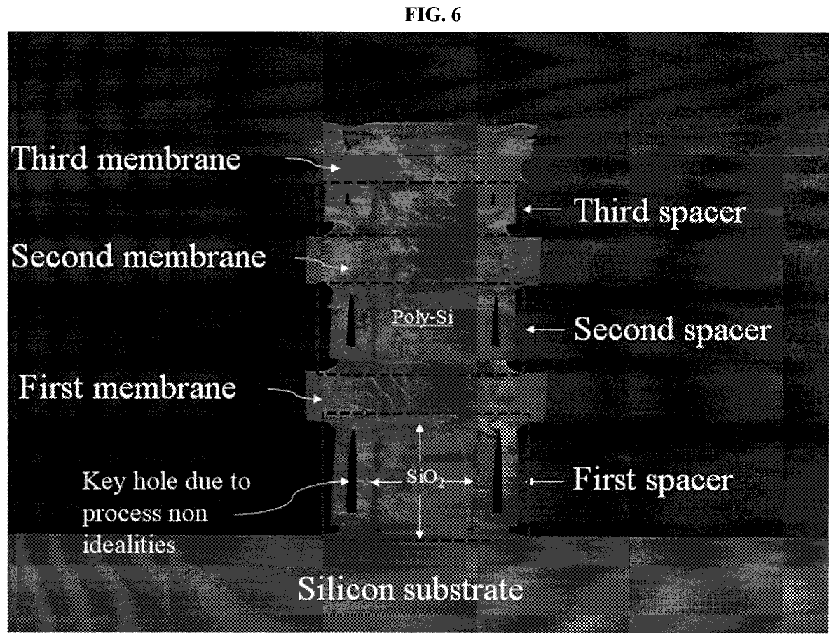

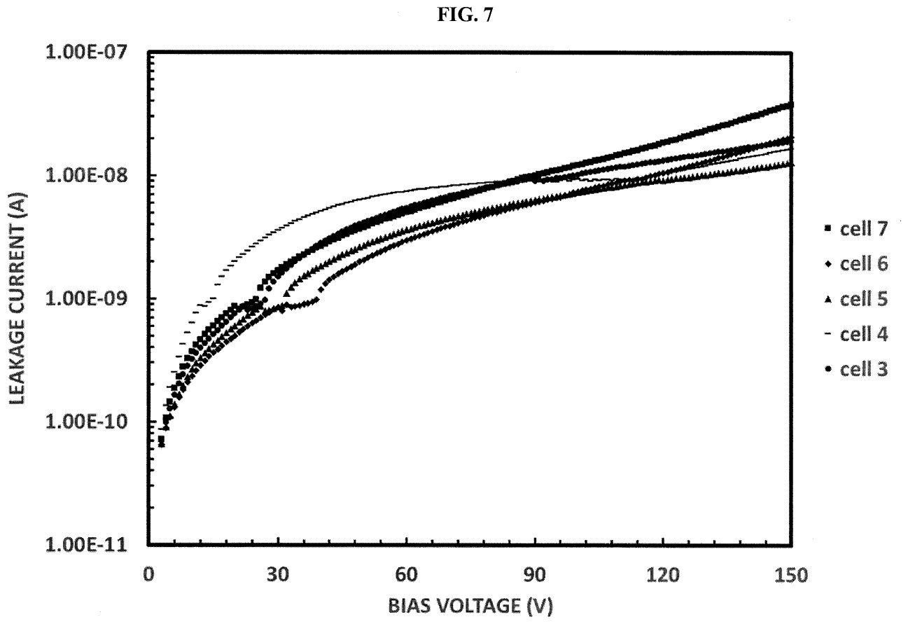

FIG. 6 shows a cross-sectional image of a scanning electron microscopy (SEM) image of a speaker device according to various embodiments. As shown in FIG. 6, the device includes stacked spacer. The key holes inside the spacers may be a result of process non-idealities and may have little or no impact on device functionality.

FIG. 7 shows a plot of leakage current (in amperes or A) as a function of bias voltage (in volts or V) showing electrical testing results of a fully fabricated device for leakage current and breakdown voltage between the membranes.

Leakage is less than 30 nA and no breakdown observed up to 150 V. Five devices may be measured at various locations on the wafers.

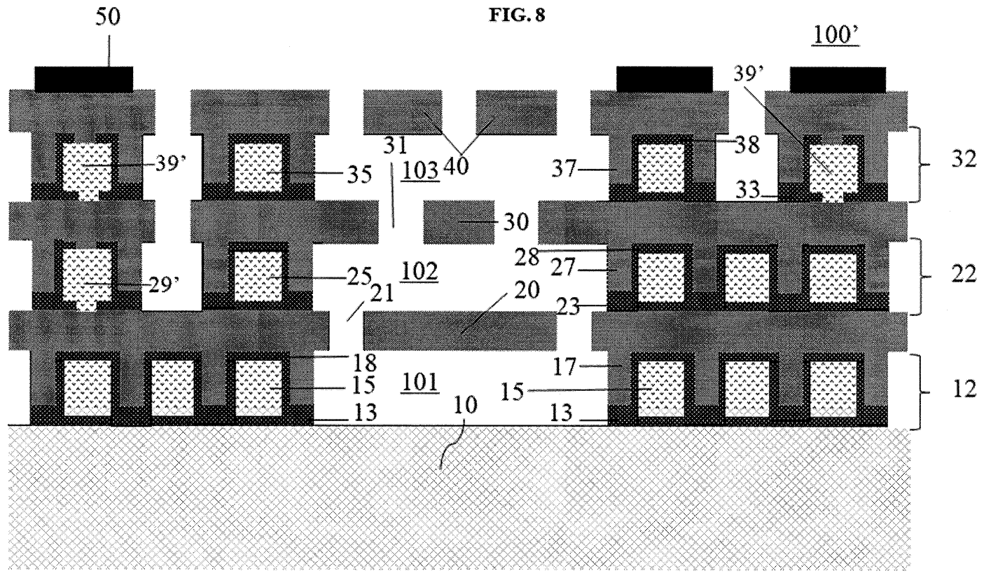

FIG. 8 shows an acoustic device or platform 100′ according to various embodiments. The device or platform 100′ may be similar to the device or platform 100 shown in FIG. 1, but with the electrical routings 29′, 39′ implemented using a semiconductor such as sacrificial silicon or poly-Si.

In order to form electrical routing 29′, the third insulator layer 23 may be etched and the second semiconductor core 25 may be in physical and electrical contact with the underlying first membrane 20. The fourth insulator layer 28 may also be etched and the second membrane 30 may be in physical and electrical contact with the second semiconductor core 25. The electrical routing 29′ may electrically connect the first membrane 20 and the second membrane 30.

In order to form electrical routing 39′, the fifth insulator layer 33 may be etched and the third semiconductor core 35 may be in physical and electrical contact with the underlying second membrane 30. The sixth insulator layer 38 may also be etched and the third membrane 40 may be in physical and electrical contact with the third semiconductor core 35. The electrical routing 39′ may electrically connect the second membrane 30 and the third membrane 40.

Various embodiments may provide a MEMS platform including a substrate, stacked acoustic chambers on the substrate, perforated vibrating membranes vertically defining the acoustic chambers, and spacers anchoring the membranes and providing lateral boundary conditions to the acoustic chambers.

At least three acoustic chambers may be vertically stacked and may be in fluidic communication with each other through holes in membranes.

The perforation in adjacent membranes may be out of phase (during operation).

All the membranes may be made of heavily doped poly-silicon. The electrical routing from the membrane to the top may be carried out either by doped poly-silicon plugs inside the sacrificial silicon or through sacrificial.

The metal pads may be placed on the top membrane to access all the stacked membranes with isolation embedded in membranes to avoid cross talk.

All the spacers may be non-conducting to keep membranes electrically isolated with each other and with the substrate. The spacers may be made of sacrificial poly-silicon, preferably un-doped poly-silicon, wrapped in silicon dioxide.

The poly-silicon may be thicker than the wrapping oxide.

Inter-digitization of membrane and spacer may be carried out to increase the contact area between the two for improving adhesion strength. The oxide thickness may be modulated in the spacer template to keep electrical breakdown high and electrical leakage low.

Various embodiments may provide a method of fabricating a MEMS platform arrangement. The method may include depositing or thermally growing an oxide layer onto a silicon substrate, depositing a sacrificial poly-silicon, preferably un-doped, layer on the oxide layer, forming a template for spacer in the sacrificial layer by patterning and etching the sacrificial layer down to the oxide layer, depositing second oxide layer, depositing a doped conducting poly-silicon layer to act a functional first membrane forming perforation in the membrane tuned for device functionality and performance and utilized for sacrificial release in the fabrication process, depositing third oxide layer for protecting the first membrane, forming holes in the oxide layer through patterning and etch process to either access the sacrificial for release or the first membrane for electrical communication, repeating the above stated process three times to form the complete device, forming the plug holes in second and third sacrificial layers through patterning and etch for electrical feed through to first and second membranes, adding metal pads by depositing aluminum or its alloys and performing pattern transfer remove sacrificial poly-silicon layer in XeF₂ or SF₆ and strip thin layer of protection oxide in vaporized hydrofluoric acid (VHF).

At least three acoustic chambers may be vertically stacked and may be in fluidic communication with each other through holes in membranes.

The perforations in adjacent membranes may be out of phase.

All the membranes may be made of heavily doped poly-silicon and may have thickness in the range of 1 to 3 μm. The electrical routing from the membrane to the top may be carried out either by doped poly-silicon plugs inside the sacrificial silicon or through sacrificial.

The metal pads may be placed on the top membrane to access all the stacked membranes with isolation to avoid cross talk.

All the spacers may be non-conducting to keep membranes electrically isolated with each other and with the substrate.

The spacers may be made of sacrificial poly-silicon, preferably un-doped poly-silicon, wrapped in silicon dioxide.

The poly-silicon may be thicker than the wrapping oxide.

Inter-digitization of membrane and spacer may be carried out to increase the contact area between the two for improving adhesion strength.

The oxide thickness may be modulated in the spacer template to keep electrical breakdown high and electrical leakage low.

The platform may be fabricated by depositing a sequence of protection oxide—poly-silicon sacrificial—protection oxide—poly-silicon membrane layers on to a silicon substrate.

The major processes may be modular—may start with depositing a sacrificial layer and end with membrane layer.

The deposition sequence of sacrificial and membrane may be repeated three times. All the sacrificial layers may be physically connected via through holes in membranes to allow complete release of the device.

The membrane layers may be fully wrapped in silicon dioxide but may be electrically connected to allow access from the bond pads.

The poly-Si may be deposited using low pressure or atmospheric pressure chemical vapour deposition (CVD) processes. The silicon dioxide used in spacers may be either thermally grown or deposited using CVD method.

The bond pads may be formed of A1 or A1 alloy and may be defined over the solid surface, meaning the sacrificial material under the bond pads is not released. The solid surface under the bond pads may include only the oxide and poly-silicon multilayers deposited in the fabrication process of the device.

The electrical feed through to first and second membrane may be created without drilling a hole in the sacrificial layers. The method may include forming a hole the oxide deposited on the first membrane; forming a hole in the oxide deposited on top of the second sacrificial layer with two holes being in good alignment; depositing doped poly-silicon conductive layer for second membrane layer; and repeating the same process between second and third membranes.

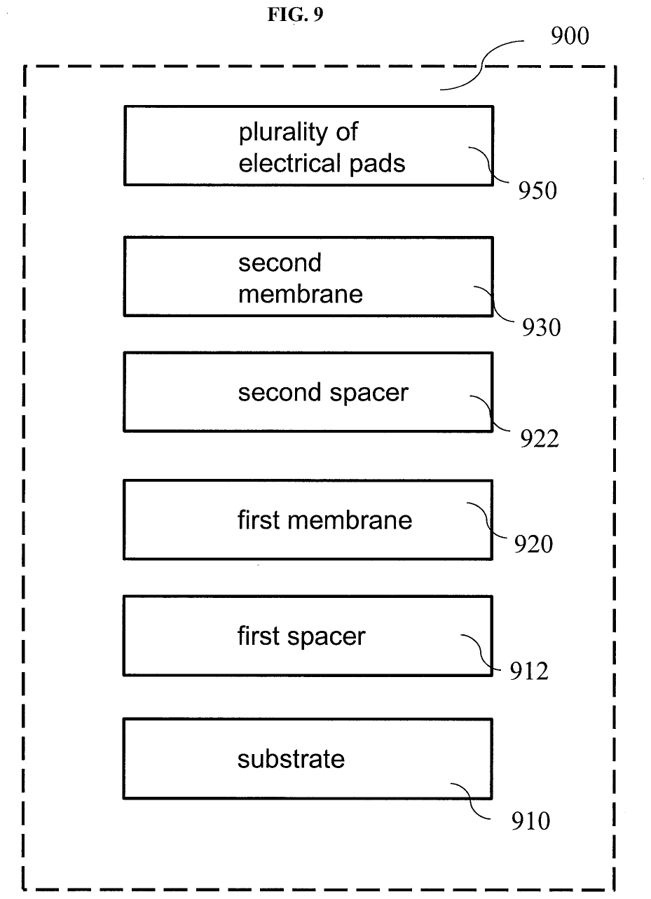

FIG. 9 shows an acoustic device 900 according to various embodiments. The acoustic device 900 may include a substrate 910. The acoustic device 900 may further include an electrically conductive first membrane 920. The acoustic device 900 may also include a first spacer 912 holding the first membrane 920 to form a first acoustic chamber between the substrate 910 and the first membrane 920. The acoustic device 900 may additionally include an electrically conductive second membrane 930. The acoustic device 900 may also include a second spacer 922 holding the second membrane 930 to form a second acoustic chamber between the first membrane 920 and the second membrane 930. The acoustic device 900 may additionally include a plurality of electrical pads 950 in electrical connection with the first membrane 920 and the second membrane 930. The first spacer 912 may include a first semiconductor core, a first insulator layer between the first semiconductor core and the substrate, and a second insulator layer between the first semiconductor core and the first membrane. The second spacer 922 may include a second semiconductor core, a third insulator layer between the second semiconductor core and the first membrane, and a fourth insulator layer between the second semiconductor core and the second membrane.

The acoustic device 900 may be an arrangement including a substrate, a first spacer 912 on the substrate 910, a first membrane 920 on the first spacer 912, a second spacer 922 on the first membrane 930, a second membrane 930 on the second spacer 922, and a plurality of electrical pads 950 in electrical connection with the first membrane 920 and the second membrane 930.

The acoustic device 900 may also include an electrically conductive third membrane. The acoustic device 900 may further include a third spacer holding the third membrane to form a third acoustic chamber between the second membrane 930 and the third membrane. The plurality of electrical pads 950 may also be in electrical connection with the third membrane. In various embodiments, the substrate may include a through silicon hole to access the first acoustic chamber.

The third spacer may further include a third semiconductor core, a fifth insulator layer between the third semiconductor core and the second membrane, and a sixth insulator layer between the third semiconductor core and the third membrane.

In various embodiments, the first semiconductor core may be thicker than the first insulator layer and/or the second insulator layer. The second semiconductor core may be thicker than the third insulator layer and/or the fourth insulator layer. The third semiconductor core may be thicker than the fifth insulator layer and/or the sixth insulator layer.

The plurality of electrical pads 950 may be on the third membrane. The plurality of electrical pads 950 may be metal pads including a metal such as aluminum.

The first semiconductor core, the second semiconductor core, and/or the third semiconductor core may include polysilicon (poly-Si).

The first membrane 920, the second membrane 930, and/or the third semiconductor membrane may include doped polysilicon, i.e. polysilicon doped with one or more dopants such as phosphorous.

The first insulator layer, the second insulator layer, the third insulator layer, the fourth insulator layer, the fifth insulator layer, and/or the sixth insulator layer may include silicon oxide.

The first membrane 920 and the second membrane 930 may be electrically connected by a first electrical conduction pathway. The second membrane 930 and the third membrane may be electrically connected by a second electrical conduction pathway.

In various embodiments, the first electrical conduction pathway may include a first plug extending from a first surface of the second spacer 922 to a second surface of the second spacer 922 opposite the first surface. The second electrical conduction pathway may include a second plug extending from a first surface of the third spacer to a second surface of the third spacer opposite the first surface.

In various other embodiments, the third insulator layer may include a first through hole and the fourth insulator layer may include a second through hole, the first through hole and the second through hole including one or more electrically conductive materials so that the electrically conductive material and the second semiconductor core form the first electrical conduction pathway. For instance, the first through hole may include a material comprised in the second semiconductor core, e.g. polysilicon, and the second through hole may include a material comprised in the second membrane 930, e.g. doped polysilicon.

The fifth insulator layer may include a third through hole and the sixth insulator layer may include a fourth through hole, the third through hole and the fourth through hole including one or more electrically conductive materials so that the one or more electrically conductive materials and the third semiconductor core form the second electrical conduction pathway. For instance, the third through hole may include a material comprised in the third semiconductor core, e.g. polysilicon, and the fourth through hole may include a material comprised in the third membrane, e.g. doped polysilicon.

The first membrane 920 may include one or more through-holes extending from a first surface of the first membrane 920 to a second surface of the first membrane 920 opposite the first surface so that the first acoustic chamber is in fluidic communication with the second acoustic chamber.

The second membrane 930 may include one or more through-holes extending from a first surface of the second membrane 930 to a second surface of the second membrane 930 opposite the first surface so that the second acoustic chamber is in fluidic communication with the third acoustic chamber.

The third membrane may also include one or more through-holes extending from a first surface of the third membrane to a second surface of the third membrane opposite the first surface so that the third acoustic chamber is exposed to the environment.

The through-holes may alternatively be referred to as perforations. The acoustic chambers may be air chambers.

In various embodiments, at least a portion of the first spacer 912 and at least a portion of the first membrane 920 may be interdigitated; At least a portion of the second spacer 922 and at least a portion of the second membrane 930 may be interdigitated. At least a portion of the third spacer and at least a portion of the third membrane may be interdigitated.

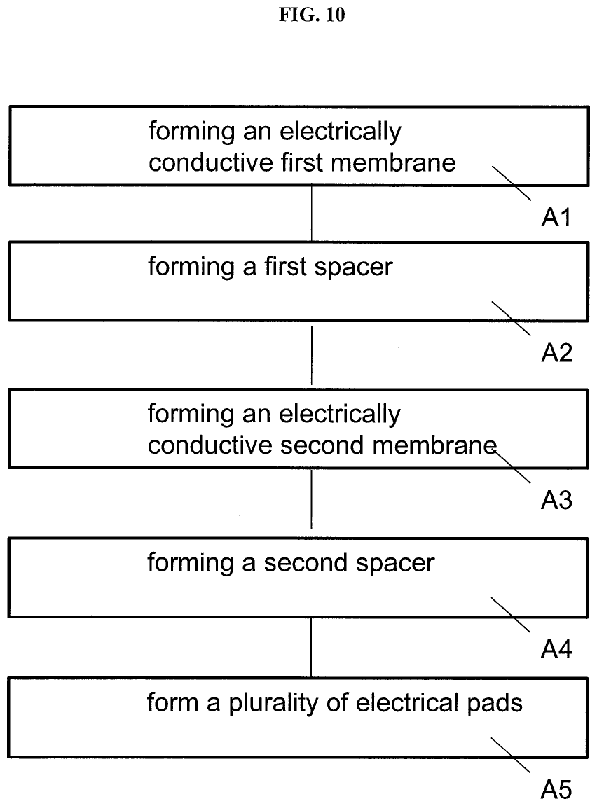

FIG. 10 is a schematic showing a method of forming an acoustic device according to various embodiments. The method may include, in A1, forming an electrically conductive first membrane. The method may also include, in A2, forming a first spacer holding the first membrane to form a first acoustic chamber between a substrate and the first membrane. The method may further include, in A3, forming an electrically conductive second membrane. The method may additionally include, in A4, forming a second spacer holding the second membrane to form a second acoustic chamber between the first membrane and the second membrane. The method may also include, in A5, forming a plurality of electrical pads in electrical connection with the first membrane and the second membrane. The first spacer may also include a first semiconductor core, a first insulator layer between the first semiconductor core and the substrate, and a second insulator layer between the first semiconductor core and the first membrane. The second spacer may include a second semiconductor core, a third insulator layer between the second semiconductor core and the first membrane, and a fourth insulator layer between the second semiconductor core and the second membrane.

For avoidance of doubt, the steps illustrated in FIG. 10 is not intended to be in sequence. In other words, FIG. 10 is not intended to limit the steps in any particular sequence.

In other words, the method may include forming a device including a substrate, a first spacer, a first membrane, a second spacer, a second membrane, and a plurality of electrically conductive pads. Each spacer may have a semiconductor core, and insulator layers wrapping around or sandwiching the semiconductor core.

In various embodiments, the first spacer may be formed before forming the first membrane. The second spacer may be formed after forming the first membrane and before forming the second membrane.

In various embodiments, forming the first spacer may include forming the first insulator layer (e.g. including silicon oxide) by deposition (e.g. via CVD) or heating the substrate. Forming the first spacer may also include forming the first semiconductor core (e.g. including undoped polysilicon) by depositing a semiconductor material (e.g. via CVD); and patterning the deposited semiconductor material. Forming the first spacer may also include forming the second insulator layer (e.g. including silicon oxide) by deposition (e.g. via CVD).

Forming the first membrane may include depositing an electrically conductive material, e.g. doped polysilicon, on the first spacer; and patterning the deposited electrically conductive material.

In various embodiments, one or more through-holes extending from a first surface of the first membrane to a second surface of the first membrane opposite the first surface may be formed after forming the third insulator layer.

In various embodiments, the second insulator layer, the first membrane, and the third insulator layer may be etched in an etching step. The etching step may form the one or more through-holes in the first membrane.

In various embodiments, the method may also include forming an electrically conductive third membrane. The method may also include forming a third spacer holding the third membrane to form a third acoustic chamber between the second membrane and the third membrane. The plurality of electrical pads may also be in electrical connection with the third membrane.

The spacer may be formed after forming the second membrane and before forming the third membrane.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An acoustic device comprising:
a substrate;
an electrically conductive first membrane;
a first spacer holding the first membrane to form a first acoustic chamber between the substrate and the first membrane;
an electrically conductive second membrane;
a second spacer holding the second membrane to form a second acoustic chamber between the first membrane and the second membrane; and
a plurality of electrical pads in electrical connection with the first membrane and the second membrane;
wherein the first spacer comprises a first semiconductor core, a first insulator layer between the first semiconductor core and the substrate, and a second insulator layer between the first semiconductor core and the first membrane; and
wherein the second spacer comprises a second semiconductor core, a third insulator layer between the second semiconductor core and the first membrane, and a fourth insulator layer between the second semiconductor core and the second membrane.

2. The acoustic device according to claim 1, further comprising:
an electrically conductive third membrane; and
a third spacer holding the third membrane to form a third acoustic chamber between the second membrane and the third membrane;
wherein the plurality of electrical pads is also in electrical connection with the third membrane; and
wherein the substrate comprises a through silicon hole to access the first acoustic chamber.

3. The acoustic device according to claim 2,
wherein the third spacer comprises a third semiconductor core, a fifth insulator layer between the third semiconductor core and the second membrane, and a sixth insulator layer between the third semiconductor core and the third membrane.

4. The acoustic device according to claim 2,
wherein the plurality of electrical pads is on the third membrane.

5. The acoustic device according to claim 2,
wherein the first semiconductor core, the second semiconductor core, and the third semiconductor core comprise polysilicon.

6. The acoustic device according to claim 2,
wherein the first membrane, the second membrane, and the third semiconductor membrane comprise doped polysilicon.

7. The acoustic device according to claim 2,
wherein the first insulator layer, the second insulator layer, the third insulator layer, the fourth insulator layer, the fifth insulator layer, and the sixth insulator layer comprise silicon oxide.

8. The acoustic device according to claim 2,
wherein the first membrane and the second membrane are electrically connected by a first electrical conduction pathway; and
wherein the second membrane and the third membrane are electrically connected by a second electrical conduction pathway.

9. The acoustic device according to claim 8,
wherein the first electrical conduction pathway comprises a first plug extending from a first surface of the second spacer to a second surface of the second spacer opposite the first surface; and
wherein the second electrical conduction pathway comprises a second plug extending from a first surface of the third spacer to a second surface of the third spacer opposite the first surface.

10. The acoustic device according to claim 8,
wherein the third insulator layer comprises a first through hole and the fourth insulator layer comprises a second through hole, the first through hole and the second through hole comprising one or more electrically conductive materials so that the one or more electrically conductive materials and the second semiconductor core form the first electrical conduction pathway; and
wherein the fifth insulator layer comprises a third through hole and the sixth insulator layer comprises a fourth through hole, the third through hole and the fourth through hole comprising one or more electrically conductive materials so that the one or more electrically conductive materials and the third semiconductor core form the second electrical conduction pathway.

11. The acoustic device according to claim 2,
wherein the first membrane comprises one or more through-holes extending from a first surface of the first membrane to a second surface of the first membrane opposite the first surface so that the first acoustic chamber is in fluidic communication with the second acoustic chamber; and
wherein the second membrane comprises one or more through-holes extending from a first surface of the second membrane to a second surface of the second membrane opposite the first surface so that the second acoustic chamber is in fluidic communication with the third acoustic chamber.

12. The acoustic device according to claim 2,
wherein at least a portion of the first spacer and at least a portion of the first membrane are interdigitated;
wherein at least a portion of the second spacer and at least a portion of the second membrane are interdigitated; and
wherein at least a portion of the third spacer and at least a portion of the third membrane are interdigitated.

13. A method of forming an acoustic device, the method comprising:
forming an electrically conductive first membrane;
forming a first spacer holding the first membrane to form a first acoustic chamber between a substrate and the first membrane;
forming an electrically conductive second membrane;
forming a second spacer holding the second membrane to form a second acoustic chamber between the first membrane and the second membrane; and
forming a plurality of electrical pads in electrical connection with the first membrane and the second membrane;
wherein the first spacer comprises a first semiconductor core, a first insulator layer between the first semiconductor core and the substrate, and a second insulator layer between the first semiconductor core and the first membrane; and
wherein the second spacer comprises a second semiconductor core, a third insulator layer between the second semiconductor core and the first membrane, and a fourth insulator layer between the second semiconductor core and the second membrane.

14. The method according to claim 13,
wherein the first spacer is formed before forming the first membrane; and
wherein the second spacer is formed after forming the first membrane and before forming the second membrane.

15. The method according to claim 13,
wherein forming the first spacer comprises:
forming the first insulator layer by deposition or heating the substrate; and
forming the first semiconductor core by depositing a semiconductor material, and patterning the deposited semiconductor material, and
forming the second insulator layer by deposition.

16. The method according to claim 13,
wherein forming the first membrane comprises:
depositing an electrically conductive material on the first spacer; and
patterning the deposited electrically conductive material.

17. The method according to claim 13,
wherein one or more through-holes extending from a first surface of the first membrane to a second surface of the first membrane opposite the first surface are formed after forming the third insulator layer.

18. The method according to claim 17,
wherein the second insulator layer, the first membrane, and the third insulator layer are etched in an etching step; and
wherein the etching step forms the one or more through-holes in the first membrane.

19. The method according to claim 13, further comprising:
forming an electrically conductive third membrane; and
forming a third spacer holding the third membrane to form a third acoustic chamber between the second membrane and the third membrane;
wherein the plurality of electrical pads is also in electrical connection with the third membrane.

20. The method according to claim 19,
wherein the spacer is formed after forming the second membrane and before forming the third membrane.
